(19) United States
(12) Patent Application Publication
(10) Pub. No.: US 2003/0039207 A1
(43) Pub. Date: Feb. 27, 2003

(54) Transmission apparatus equipped with an alarm transfer device

(76) Inventors: Koichi Maeda, Fukuoka (JP); Kazuhiko Omura, Fukuoka (JP); Katsuyuki Okabe, Fukuoka (JP); Masakazu Ozaki, Kawasaki (JP)

Correspondence Address: Rosenman & Colin LLP, 15th Fl., 575 Madison Avenue, New York, NY, 10022-2511, US

(21) Appl. No.: 10/079,803

(22) Filed: Feb. 20, 2002

(30) Foreign Application Priority Data
Aug. 21, 2001 (JP) 2001-250839

(51) Int. Cl. G01R 31/08; H04L 12/28

(52) U.S. Cl. 370/216; 370/907; 370/400

(57) ABSTRACT

The present invention is directed to the provision of a transmission apparatus and, more particularly, of a transmission apparatus equipped with an alarm transfer device that enables alarm information to be transferred on a network where a protocol having a dedicated frame for achieving network management and client maintenance and a protocol that does not have such a dedicated frame are running in mixed fashion. The transmission apparatus, which is connected to the network where transparent data transmissions are performed using a plurality of client protocols, is designed to accommodate at least one of the plurality of protocols as a primary client protocol, and the alarm transfer device transfers alarm information indicating the occurrence of a failure to a destination transmission apparatus via the network, wherein the alarm information is transferred using an alarm frame created based on a prescribed client protocol unified among the plurality of client protocols.

### BACKGROUND OF THE INVENTION

1. Field of the Invention

The present invention relates to a transmission apparatus and, more particularly, to a transmission apparatus equipped with an alarm transfer device, in a network where a protocol having a dedicated frame for achieving network management and client maintenance and a protocol that does not have such a dedicated frame are running in mixed fashion.

2. Description of the Related Art

In recent years, with the rapidly increasing number of Internet users, there has developed a need to construct more reliable optical networks capable of transmitting large amounts of data at high speed. WDM (Wavelength Division Multiplexing) is a technique that addresses this issue by using the transmission capacity of existing optical fibers more efficiently. More specifically, WDM is a scheme that multiplexes a plurality of signals of different wavelengths for transmission through a single optical fiber by using the property that different wavelengths of light do not interfere with each other. The transmitted signals are separated at the receiving end.

These days, with the increasing speed of subscriber lines, enabled by such a technology as xDSL (Digital Subscriber Line), the increasing use of multimedia data, or the increasing use of the Internet itself, the amount of data flowing through the backbone of the Internet are increasing exponentially, and under such circumstances, networks that use DWDM (Dense Wavelength Division Multiplexing), a higher density version of WDM, are being constructed in order to further increase the speed and capacity of the backbone network.

Nowadays, networks employing DWDM and using optical transmission as the main transmission means are becoming the dominant network architecture, and optical transmission equipment also needs to be adapted to various applications and existing client protocols (transmission procedures) based on that network architecture. The existing client protocols include SONET/SDH (Synchronous Optical Network/Synchronous Digital Hierarchy), Fast Ethernet/FDDI (Fiber Distributed Data Interface), Gigabit Ethernet, and Fibre Channel (Ethernet is a registered trademark).

As data transfer rates between clients, SONET/SDH uses STS-3/STM-1 (155.52 Mbps), STS-12/STM-4 (622.08 Mbps), and STS-48/STM-16 (2,488.32 Mbps), Fast Ethernet/FDDI uses 125 Mbps, Gigabit Ethernet uses 1.25 Gbps, and Fibre Channel uses 132.8125 Mbps, 265.625 Mbps, 531.25 Mbps, and 1,062.5 Mbps. Networks employing DWDM are being constructed in order to achieve bit-free transmission by accommodating such a large variety of client protocols.

FIG. 1 shows one example of an optical network that uses DWDM, etc.

In FIG. 1, an optical signal from an endpoint apparatus 1 is transmitted via a relay apparatus 2 to a network apparatus 3 constructed with such elements as DWDM that multiplexes n wavelengths for transmission. The network apparatus 3 outputs individually separated optical signals, each of which is transmitted via a relay apparatus 4 and received by an endpoint apparatus 5. The transmission of an optical signal from the endpoint apparatus 5 to the endpoint apparatus 1 is performed in a similar manner. Between the endpoint apparatuses 1 and 5 at the opposite ends of the transmission path, bit-free transmission is performed based on the various client protocols described above.

In the prior art network configuration, if an input optical signal failure (such as loss of data or out-of-synchronization) occurs, for example, between the endpoint apparatus 1 and the relay apparatus 2, the location of the failure can be easily identified in the case of SONET/SDH which can transfer an alarm using a dedicated frame, because the alarm signal indicating the occurrence of the failure can be transferred without relying on the network apparatus 3. However, in the case of other client protocols such as Gigabit Ethernet and FDDI that do not have dedicated frames for network management, there arises the problem that the alarm cannot be clearly detected at the relay apparatus 4 or the endpoint apparatus 5 at the opposite end of the path and it is difficult to clearly identify the location of the failure. An example of this is shown below.

FIGS. 2 to 4 show one example of an alarm transfer method according to the prior art.

In FIG. 2, when a failure (indicated by “x”) occurs on the input side, the relay apparatus 2 detects a LOL (Loss of Light) or LOS (Loss of Signal) alarm signal. LOL is an alarm that is detected when the bit-error rate (BER) of the received signal is 1×10⁻³ or higher. LOS is an alarm that is detected when the input signal is lost, rendering it impossible to recover the clock from the received signal.

As shown in the figure, these failure states are detected (indicated by “•”) in any of the client protocols of SONET/SDH, Fast Ethernet/FDDI, Gigabit Ethernet, and Fibre Channel. Of these, only SONET/SDH has the function of generating an alarm signal indicating the occurrence of a failure (AIS (Alarm Indication Signal)-L), and transmitting the AIS-L to the relay apparatus 4 on the destination side. Accordingly, the relay apparatus 4 on the destination side can easily recognize from the received AIS-L (indicated by “•”) that a failure has occurred at the relay apparatus 2. In the illustrated example, an all ones signal indicating “communications rendered impossible” is sent to the endpoint apparatus 5.

FIG. 3 shows one example of AIS in the SONET (STS-48) frame format.

As shown in FIG. 3, AIS information is coded as “AIS-L” by inserting all ones in the Low-order three bit positions (D₇ to D₅) of the first byte (K2 #1) in the K2 byte area within the overhead of the SONET/SDH frame. At the receiving end, when the AIS-L is received, an RDI (Remote Defect Indication)-L code created by inserting “110” in the same area can be returned as response information to the sender.

Generally, the relay apparatus 2 and 4 each have a clock and data recovery (CDR) function that synchronizes the internal clock to the clock component of the received signal by using a PLL circuit within the apparatus and recovers internal data retimed by the thus synchronized internal clock. If clock recovery from the received signal becomes impossible because of the loss of the input signal, a LOS alarm is detected and the clock is switched to a free-running clock of a reference oscillator within the apparatus. In the case of SONET/SDH, a 2,488.32 MHz-based reference oscillator (155.52 MHz) is used, and with this feature, the AIS-L alarm can be transmitted to the destination side even after the LOS is detected.

On the other hand, in Fast Ethernet/FDDI, Gigabit Ethernet, and Fibre Channel, if an LOL or LOS alarm is detected (indicated by “•”) as shown in FIG. 2, since the protocol does not have a dedicated alarm transfer frame corresponding to the K2 byte in the overhead of the SONET/SDH frame shown above, there is no way to report the alarm occurrence to the destination-side relay apparatus 4 via the network apparatus 3 and, therefore, alarm transfer operations are not performed (indicated by “°”: No Operation). The resulting problem is that, at the network apparatus 3 as well as the relay apparatus 4 and endpoint apparatus 5 on the destination side, the section or location where the alarm has occurred cannot be clearly identified or is difficult to determine.

As earlier described, when the input signal is lost, and the LOS is detected, the clock is switched to the free-running clock of the reference oscillator within the apparatus, but if the apparatus is not equipped with an internal reference oscillator that matches each client protocol such as Fast Ethernet/FDDI, Gigabit Ethernet, Fibre Channel, etc., proper PLL control is not performed, and hence a correct transmission frame cannot be generated, because the clock is not synchronized to the SONET/SDH reference oscillator described earlier. This therefore necessitates the provision of a plurality of reference oscillators for the respective client protocols and a peripheral circuit for switching between the oscillators, the resulting problem being that the amount of circuitry and the size of the apparatus increase.

FIG. 4 shows an example of control flow at the time of failure detection and failure recovery in the client protocols other than SONET/SDH.

At the relay apparatus 2 on the transmitting side, error data received because of the failure occurring on its input side is transmitted out as is (No Operation), and when a LOS is detected as a result, the clock is switched to the free-running internal clock to continue the communication (S101 to S104). At the relay apparatus 4 on the receiving side, a data error is detected (blocked condition) because of the reception of the error data, and when a LOS is detected as a result, the clock is switched to the free-running internal clock (S201 to S204).

When the relay apparatus 2 is recovered from the failure, the clock is captured by the PLL because normal data is input from the client, and normal data transmission synchronized to the clock of the input data is started (S105 to S108). As a result, at the receiving relay apparatus 4 also, the clock is captured by the PLL, normal data relay operations synchronized to the clock of the received data is resumed (S205 and S206).

FIG. 5 is a diagram showing another example of the prior art alarm transfer method.

In this example, when the LOS/LOL alarm is detected at the relay apparatus 2 because of the failure occurring on its input side (indicated by “•”), the optical output of the channel (light wavelength) on which the error has been detected is shut down (indicated by “°”) to prevent the failed channel from affecting other normally operating channels. This makes it possible for the destination-side relay apparatus 4 to detect the LOS alarm arising from the occurrence of the failure, regardless of the type of client protocol used (indicated by “•”).

However, the configuration in which the network apparatus 3 transmits optically multiplexed signals using techniques such as DWDM, as in the above example, has the drawback that, if the optical output of a certain channel is shut down, the network apparatus 3 automatically adjusts the level and gain of the total optical power of the optically multiplexed signals, the network apparatus 3 thus being involved in the monitoring and control of each individual channel. In particular, in cases where the optically multiplexed signals are transmitted via a plurality of network apparatuses 3, it will take a long time to adjust the level and gain of the total optical power.

### SUMMARY OF THE INVENTION

Accordingly, it is an object of the present invention to provide a transmission apparatus equipped with an alarm transfer device that achieves, without involving the network apparatus, an alarm detection/processing function equivalent to that of SONET/SDH even in the case of the client protocols, other than SONET/SDH, that do not have the function of alarm transfer in the event of the occurrence of a failure. This makes it possible to clearly identify the location of the failure and ensure smooth network operation.

More specifically, an object of the invention is to provide a transmission apparatus equipped with an alarm transfer device whereby, in an optical network where a plurality of client protocols are running in a mixed fashion, when a failure occurs between an endpoint apparatus and a relay apparatus, an alarm indicating the occurrence of the failure is transmitted out using an alarm transfer frame unified to a SONET frame or a digital wrapper (DW) frame into which alarm information (AIS/RDI, etc.) is added.

This requires the provision of only one reference oscillator to which the operation is to be switched in the event of a failure, and eliminates the need to provide different reference oscillators for different client protocols. Furthermore, by using the alarm information within the unified frame, it becomes possible to transfer and detect the alarm between optical transmission apparatuses without the intervention of the network apparatus.

According to the present invention, there is provided a transmission apparatus which is connected to a network where transparent data transmissions are performed using a plurality of client protocols, and which is designed to accommodate at least one of the plurality of protocols as a primary client protocol, wherein the transmission apparatus is equipped with an alarm transfer device for transferring alarm information indicating the occurrence of a failure to a destination transmission apparatus via the network, and the alarm transfer device transfers the alarm information by using an alarm frame created based on a prescribed client protocol unified among the plurality of client protocols.

The alarm transfer device performs switching from the primary client protocol to the prescribed unified client protocol when a failure is detected, and performs switching from the prescribed unified client protocol to the primary client protocol when recovery from the failure is detected. The prescribed unified client protocol is a protocol having a dedicated frame for network management and maintenance, and the primary client protocol is a protocol that does not have a dedicated frame for network management and maintenance. The alarm frame is a SONET/SDH frame or a digital wrapper frame.

### BRIEF DESCRIPTION OF THE DRAWINGS

The present invention will be more clearly understood from the description as set forth below with reference to the accompanying drawings.

FIG. 1 is a diagram showing one example of an optical network that uses DWDM, etc.

FIG. 2 is a diagram showing one example of an alarm transfer method according to the prior art.

FIG. 3 is a diagram showing an example of AIS contained in a SONET (STS-48) frame.

FIG. 4 is a diagram showing an example of control flow at the time of failure detection and failure recovery in client protocols other than SONET/SDH.

FIG. 5 is a diagram showing another example of the prior art alarm transfer method.

FIG. 6 is a diagram illustrating the operation of the present invention during normal network operations.

FIG. 7 is a diagram illustrating the operation of the present invention when a failure has occurred.

FIG. 8 is a diagram showing a first embodiment of an optical transmission apparatus according to the present invention.

FIG. 9 is a diagram showing an example of the configuration of FIG. 8 in further detail.

FIG. 10 is a diagram showing one example of control flow (1) in the embodiment of FIG. 9.

FIG. 11 is a diagram showing one example of control flow (2) in the embodiment of FIG. 9.

FIG. 12 is a diagram showing one example of control timing (1) in the embodiment of FIG. 9.

FIG. 13 is a diagram showing one example of control timing (2) in the embodiment of FIG. 9.

FIG. 14 is a diagram illustrating one example of alarm transfer operation (1) according to the first embodiment of the present invention.

FIG. 15 is a diagram illustrating one example of alarm transfer operation (2) according to the first embodiment of the present invention.

FIG. 16 is a diagram showing a second embodiment of an optical transmission apparatus according to the present invention.

FIG. 17A is a diagram showing one example of a digital wrapper frame structure (1).

FIG. 17B is a diagram showing one example of a digital wrapper frame structure (2).

FIG. 17C is a diagram showing one example of a digital wrapper frame structure (3).

FIG. 18 is a diagram illustrating one example of alarm transfer operation (1) according to the second embodiment of the present invention.

FIG. 19 is a diagram illustrating one example of alarm transfer operation (2) according to the second embodiment of the present invention.

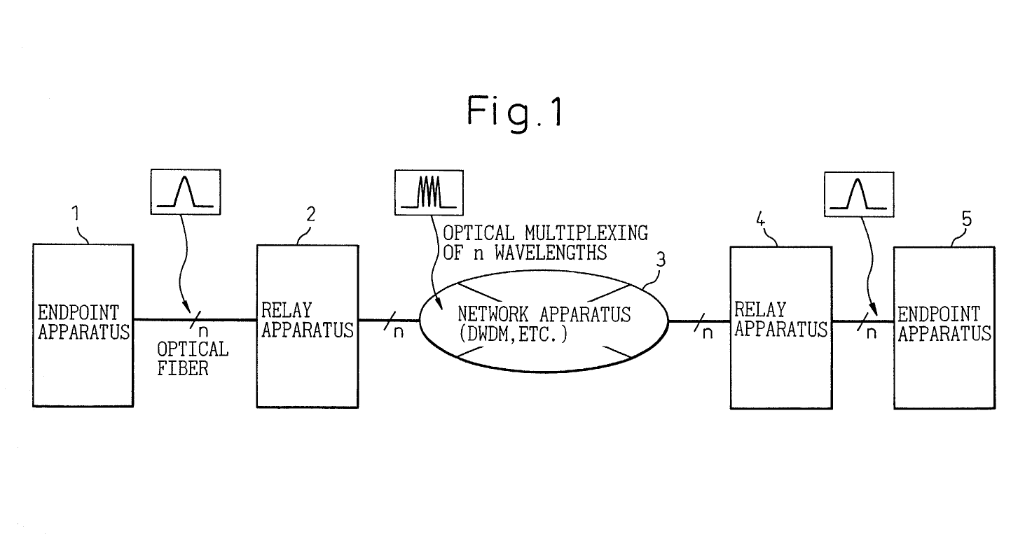

### DESCRIPTION OF THE PREFERRED EMBODIMENTS

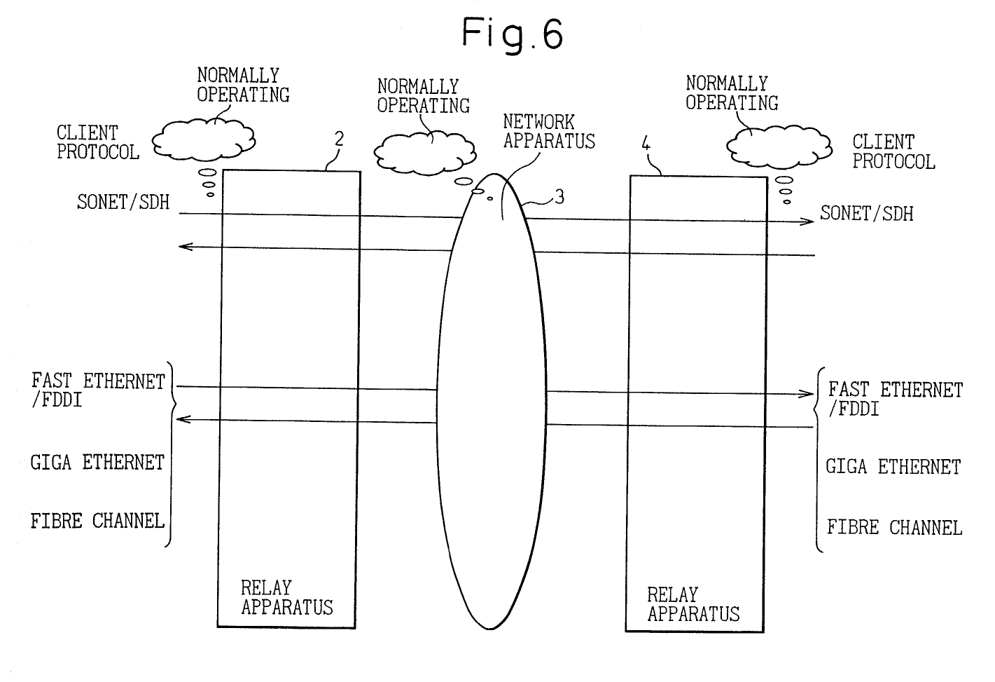

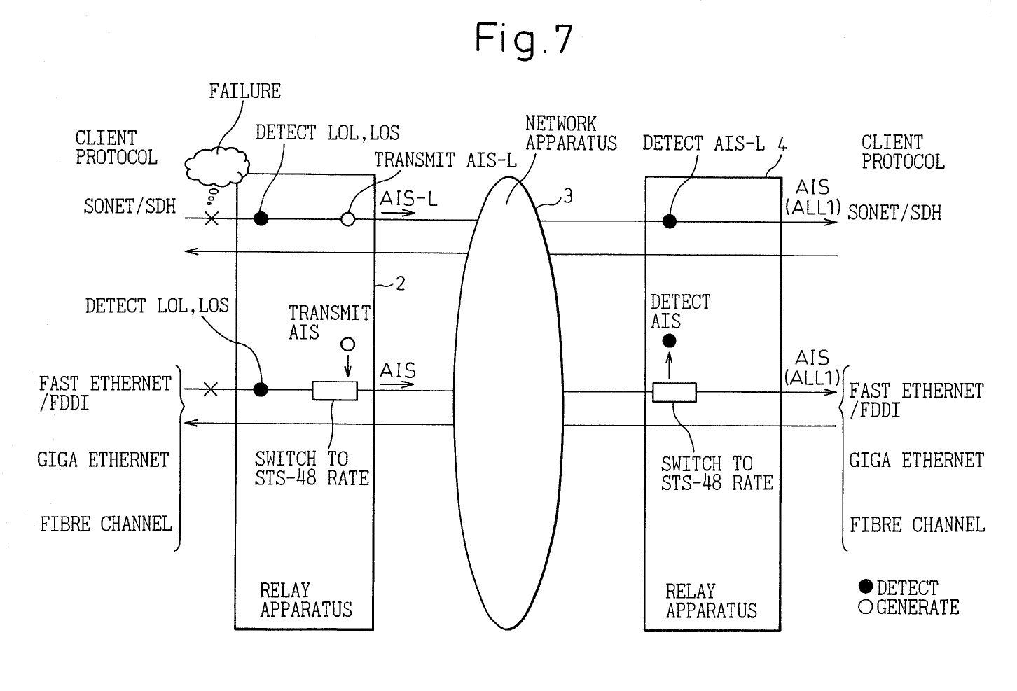

FIGS. 6 and 7 are diagrams illustrating an operation according to the present invention. FIG. 6 shows an example of an operation when the network is operating normally, and FIG. 7 shows an example of an operation when a failure has occurred. As a method that does not involve the network apparatus 3 in alarm transfer operations, a SONET transmission frame is used as a unified frame for alarm transfer in any client protocol that does not have a dedicated frame for alarm transfer.

During the normal operation shown in FIG. 6, transparent data transmission is performed between relay apparatuses 2 and 4 via the network apparatus 3 according to the protocol specification, i.e., the frame format, data transmission speed, etc., of the client protocol of SONET/SDH, Fast Ethernet/FDDI, Gigabit Ethernet, or Fibre Channel.

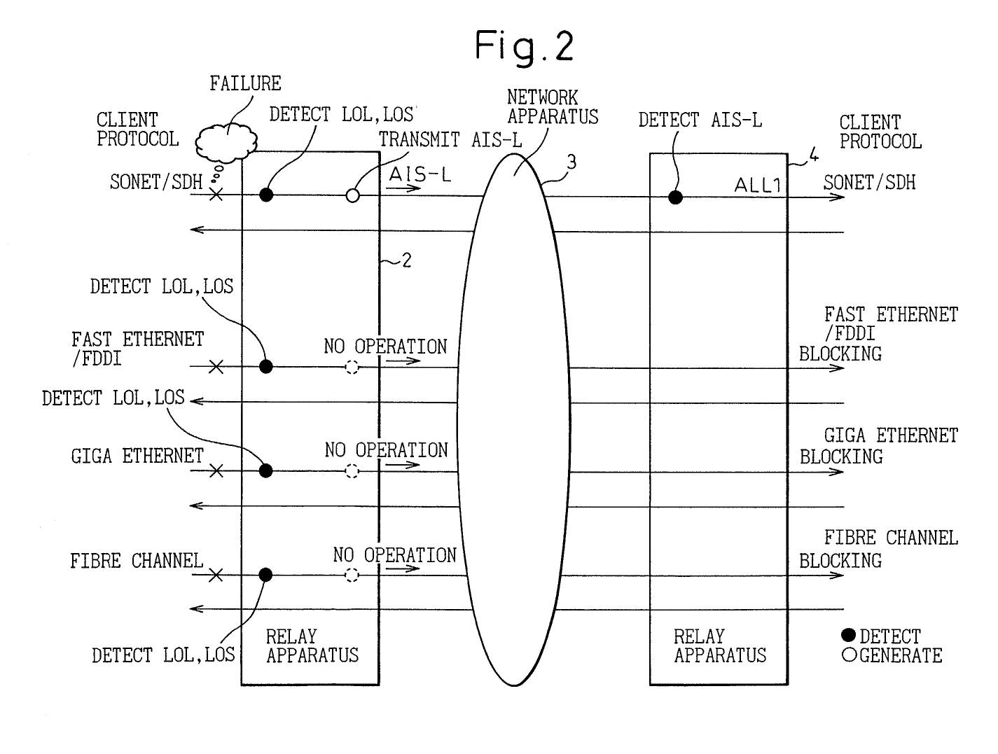

When a failure occurs as shown in FIG. 7, the client protocol running in the relay apparatus 2 detects a LOL or LOS (indicated by “•”) due to the failure (indicated by “x”) occurring on its input side. When the client protocol is SONET/SDH, an alarm indication signal AIS-L indicating the occurrence of the failure is generated and transmitted (indicated by “°”) to the destination-side relay apparatus 4, as in the case of the prior art shown in FIG. 2. From the received AIS-L (indicated by “•”), the destination-side relay apparatus 4 can detect that a failure has occurred at the relay apparatus 2.

Further, in the illustrated example, even when the client protocol used is not SONET/SDH, an alarm indication signal AIS-L indicating the occurrence of the failure is likewise generated and transmitted (indicated by “°”) to the destination-side relay apparatus 4. From the received AIS-L (indicated by “•”), the destination-side relay apparatus 4 can detect that a failure has occurred at the relay apparatus 2. This is accomplished because in the relay apparatuses 2 and 4, not only the clock is switched from the externally synchronized clock to the free-running internal clock upon detection of the failure, but at the same time, the client protocol is also switched temporarily to SONET/SDH.

Accordingly, in this case, only one reference clock, for example, a 155.52-MHz clock for SONET/SDH, must be provided within the apparatus. Furthermore, the existing SONET/SDH hardware and software resources for failure processing can be shared with non-SONET/SDH protocols, and the unification of the protocol for failure processing can also be achieved.

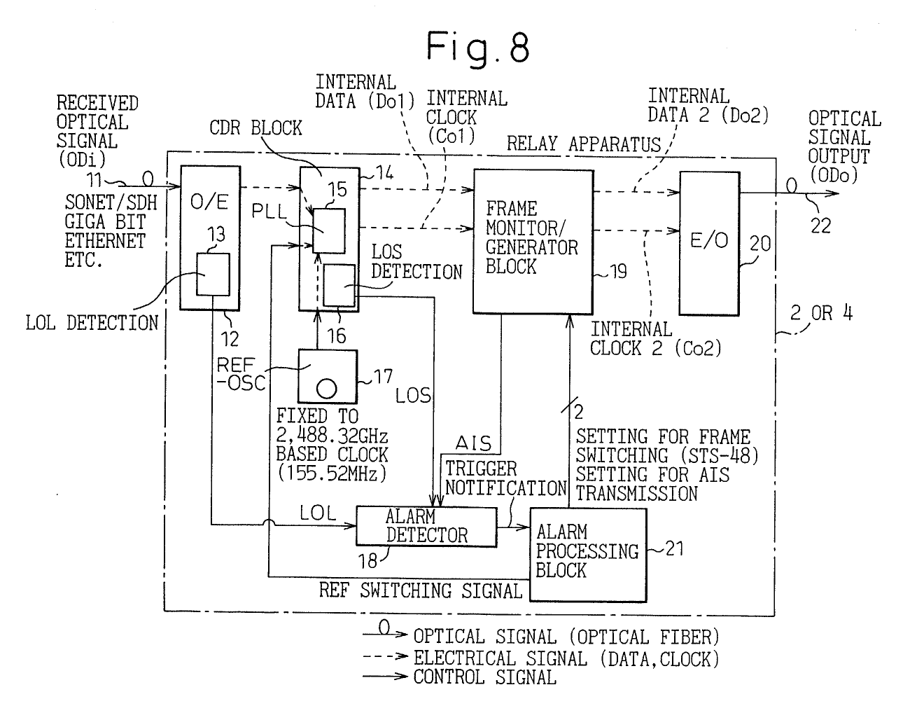

FIGS. 8 to 13 are diagrams showing an embodiment of an optical transmission apparatus that achieves the operating principle of the present invention.

FIG. 8 is a diagram showing a first embodiment of the optical transmission apparatus according to the present invention.

At the transmitting-side optical transmission apparatus 2, an optical signal received from an optical fiber 11 is converted by an optical-to-electrical converter (O/E) 12 into an electrical signal. An internal LOL detection circuit 13 detects a LOL alarm based on the bit-error rate (BER) of the input signal. The LOL alarm is fed to an alarm detector 18.

The received electrical signal from the optical-to-electrical converter 12 is fed to a clock and data recovery (CDR) block 14, where the internal clock (CO1) is synchronized to the clock component of the received signal by using a PLL circuit 15 and internal data (DO1) retimed by the internal clock is recovered. A LOS detection circuit 16 detects a LOS when the input signal is lost and clock recovery from the received signal becomes impossible. The resulting LOS alarm is fed to the alarm detector 18.

A reference oscillator (REF-OSC) 17 generates a free-running reference clock signal. In the illustrated example, the oscillator is fixed to a 2,488.32 MHz-based clock, as in the prior art, and by switching the clock at the time of a failure, a 2,488.32 MHz clock (C01′) and internal data (D01′), retimed by that clock, are output to a frame monitor/generator block 19.

In the illustrated example, the frame monitor/generator block 19 generates an STS-48 (2,488.32 Mbps) data frame (D02, C02) from the received internal clock (C01 or C01″) and internal data (D01 or D01′). When the occurrence of a failure is detected, alarm information created by inserting AIS-L in the prescribed header byte (K2 #1) in the above frame is sent out.

An electrical-to-optical converter (E/O) 20 converts the data frame signal (D02, C02), fed from the frame monitor/generator block 19, into an optical signal which is output on an optical fiber 22 for transmission to the network apparatus 3. On the other hand, the alarm detector 18, upon detecting one of three alarms, LOL or LOS described above or AIS described later, sends a notification to an alarm processing block 21. The alarm processing block 21 that received the notification sends a clock switching instruction to the clock and data recovery block 14, while also instructing the frame monitor/generator block 19 to switch the frame to the STS-48 frame, the unified frame to be used at the time of a failure, and transmit out AIS.

The operation at the receiving-side optical apparatus 4 is similar to the operation described above. When a blocked condition occurs due to a data error, a LOS or LOF is detected and, triggered by the detected signal, an operating procedure similar to that described above is initiated. Further, the frame monitor/generator block 19 detects the AIS-L information contained in the received data, and supplies it to the alarm detector 18. Then, an all ones signal is transmitted to the endpoint apparatus 5.

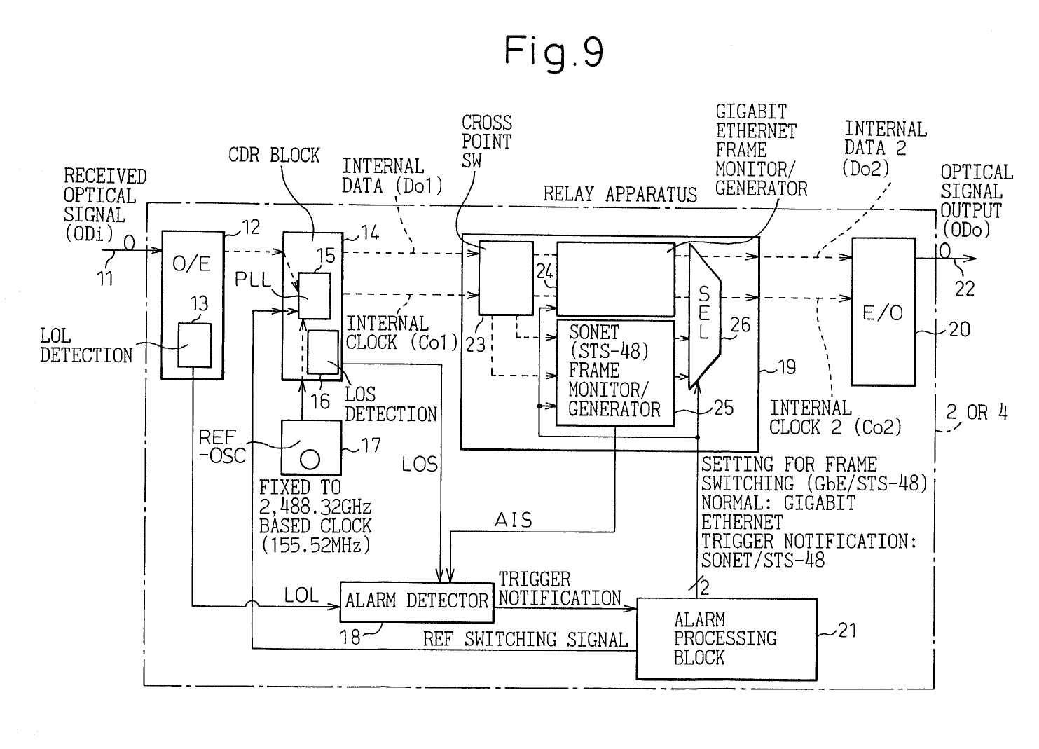

FIG. 9 is a diagram showing an example of the configuration of FIG. 8 in further detail.

This example specifically shows the detailed configuration of the frame monitor/generator block 19, and the other elements are the same as those shown in FIG. 8 and will not be further described here.

The frame monitor/generator block 19 in this example assumes the use of Gigabit Ethernet as the client protocol, and contains a Gigabit Ethernet frame monitor/generator 24 and a SONET frame monitor/generator 25 in case of failure.

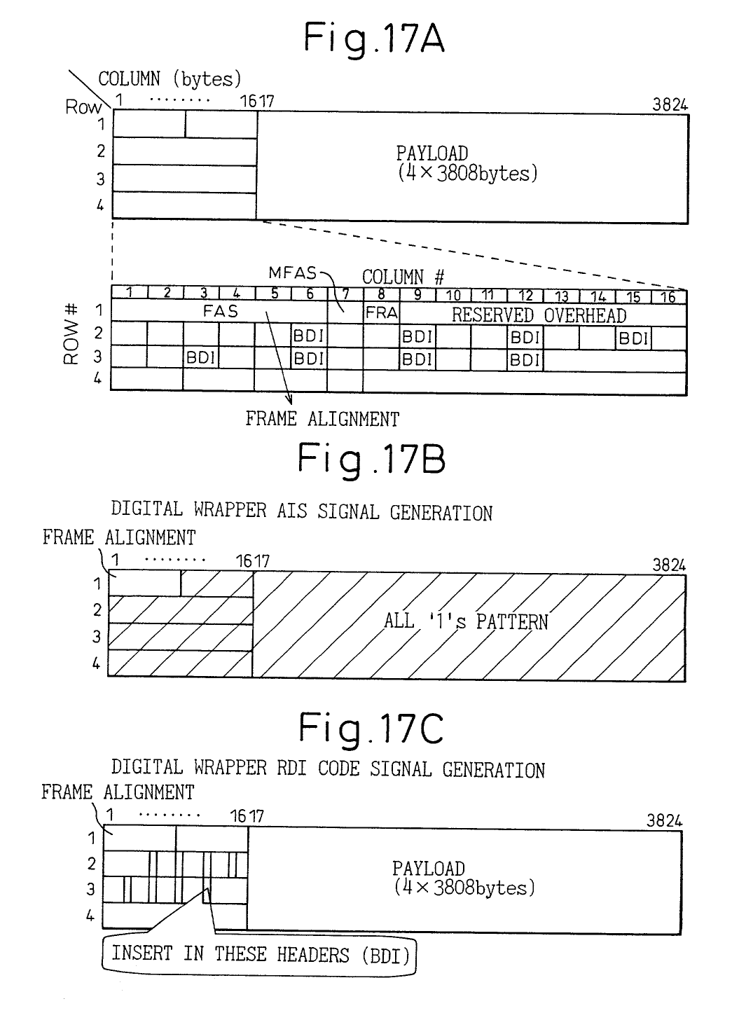

Here, the SONET frame monitor/generator 25 can be implemented as dedicated hardware integrated, for example, within the same chip as the Gigabit Ethernet frame monitor/generator 24, or can be implemented as software of a bit-free type general-purpose frame monitor/generator that is realized by the setting and processing operations of the CPU of the alarm processing block 21, as in the example of FIG. 17 to be described later.

A cross point switch 23 separates the input signal in a ratio of 1:2 for output to both the Gigabit Ethernet frame monitor/generator 24 and the SONET frame monitor/generator 25. A selector (SEL) 26, under instruction from the alarm processing block 21, selects the Gigabit Ethernet frame monitor/generator 24 during normal operation or after recovery from a failure, and selects the SONET frame monitor/generator 25 in the event of a failure.

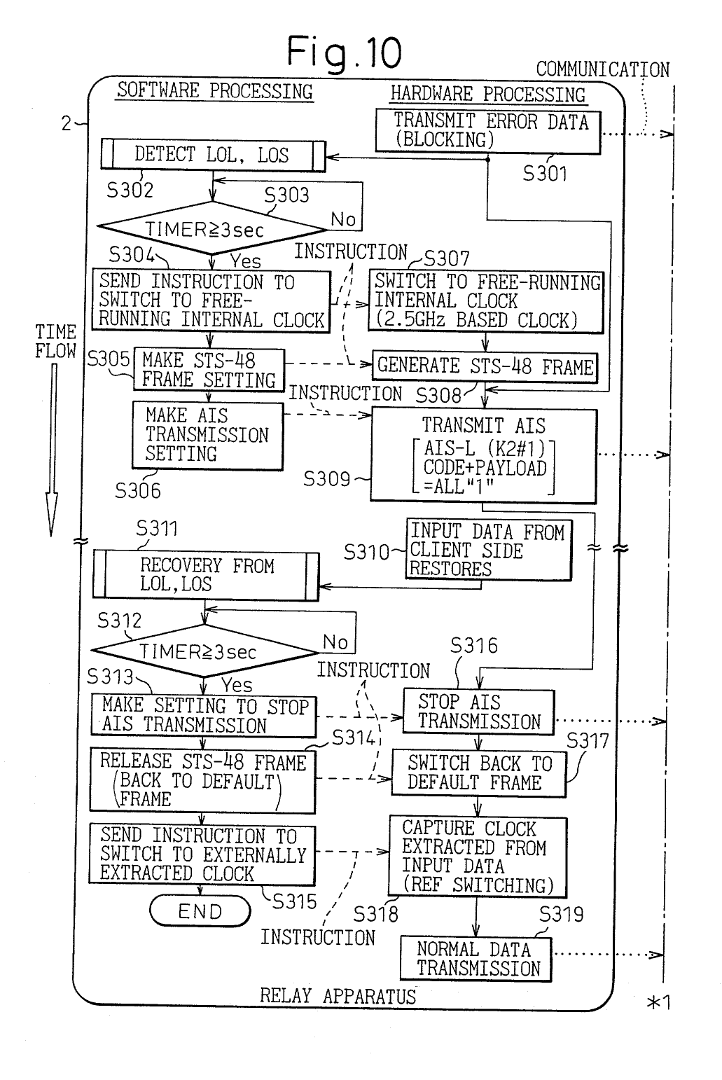

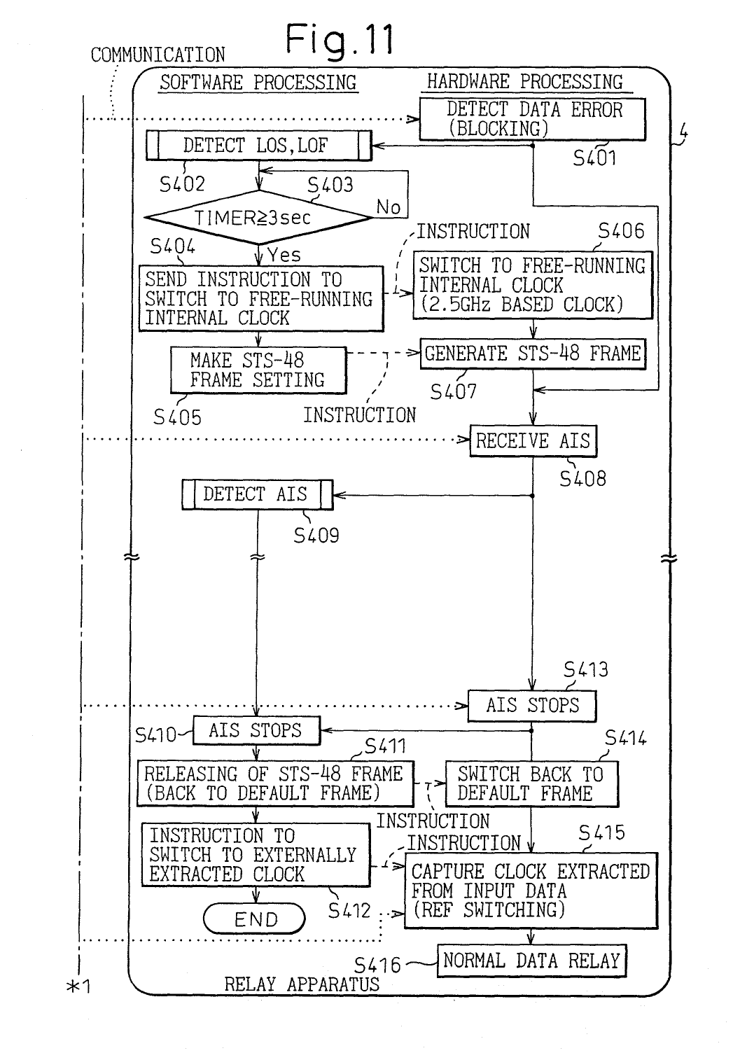

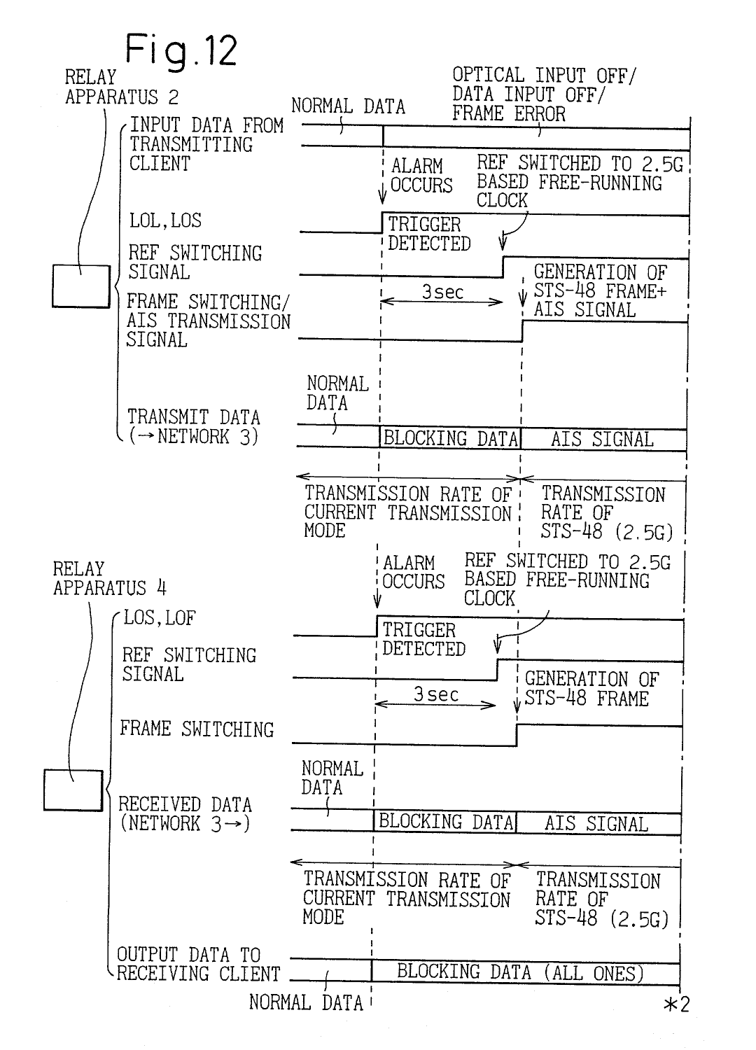

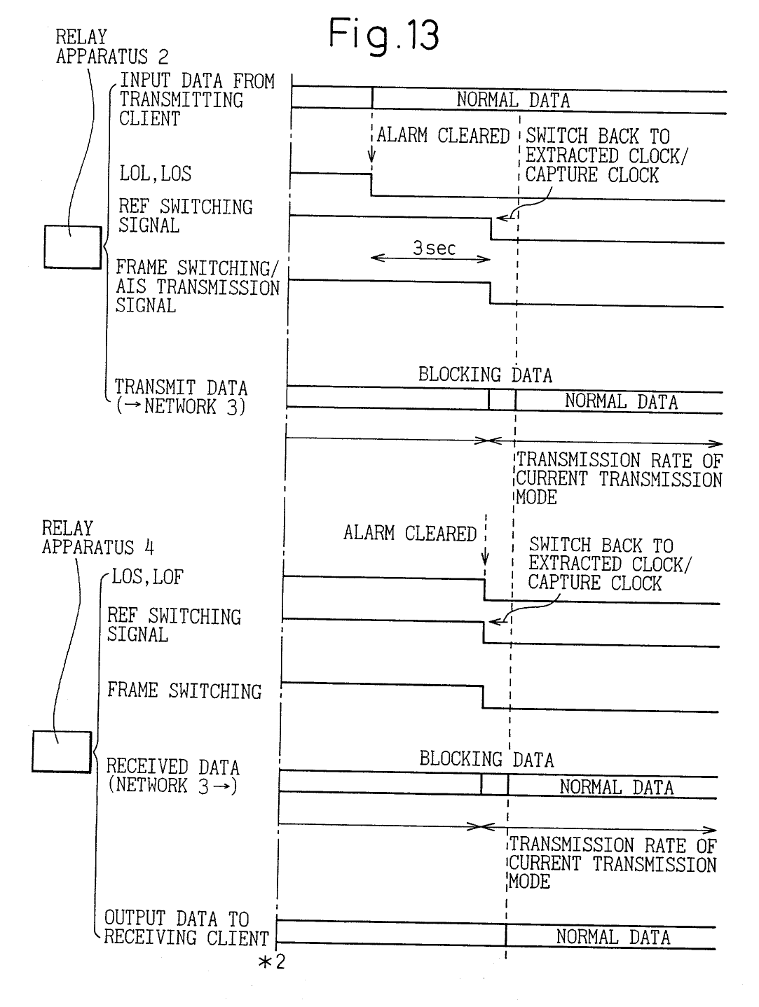

FIGS. 10 and 11 show one example of control flow in the embodiment of FIG. 9. FIGS. 12 and 13 show the control flow in the form of a timing chart. The following description is given by dealing mainly with the control flow shown in FIGS. 10 and 11, but FIGS. 12 and 13 should also be referred to as needed.

At the transmitting-side relay apparatus 2 shown in FIG. 10, error data received because of the occurrence of a failure on the input side during communication using the Gigabit Ethernet protocol is transmitted as is (S301). When a LOL or LOS is detected as a result, a timer that counts a predetermined time (in this example, three seconds) is started to prevent erroneous detection (S302 and S303). At the expiration of the count, the clock is switched to the free-running internal clock, an STS-48 frame is set up, and the transmission setting for AIS is made (S304 to S306). With these settings, an alarm frame, a 2,488.32-Mbps STS-48 frame with AIS-L carried in the header area and all ones inserted in the payload area, is transmitted to the receiving relay apparatus 4 by using the SONET/SDH protocol (S307 to S309).

Thereafter, when the relay apparatus 2 recovers from the failure, normal data based on the Gigabit Ethernet is received from the client; here again, the timer that counts the predetermined time (in this example, three seconds) is started to prevent erroneous detection in recovering from the LOL or LOS (S311 and S312). At the expiration of the count, settings are made to stop the transmission of the AIS and to release the STS-48 frame, and an instruction to switch to the externally extracted clock is issued (S313 to S315). With these operations, the protocol is switched back to Gigabit Ethernet, the primary client protocol, and the clock is captured by the PLL circuit 15, thus restoring the normal data communication condition (S316 to S319).

At the receiving-side relay apparatus 4 shown in FIG. 11, a LOL or LOS is detected because of the error data received from the transmitting-side relay apparatus 2 during communication using the Gigabit Ethernet protocol; at the receiving end also, the timer that counts the predetermined time (in this example, three seconds) is started to prevent erroneous detection (S401 and S403). At the expiration of the count, the clock is switched to the free-running internal clock, and an STS-48 frame is set up (S404 and S405), thus making it possible to receive and detect the AIS-L carried in the 2,488.32-Mbps STS-48 frame in accordance with the SONET/SDH protocol (S406 to S408).

Thereafter, when the relay apparatus 2 recovers from the failure, the relay apparatus 2 stops transmitting the AIS-L (S410 and S413), whereupon settings are made to release the STS-48 frame and to issue an instruction to switch to the externally extracted clock (S411 and S412). With these operations, the protocol is switched back to Gigabit Ethernet, the primary client protocol, and the clock is captured by the PLL circuit 15, thus restoring the normal data communication condition (S414 to S416). The distinction between the software processing and hardware processing shown in FIGS. 10 and 11 is only for purposes of convenience, and is not restrictive.

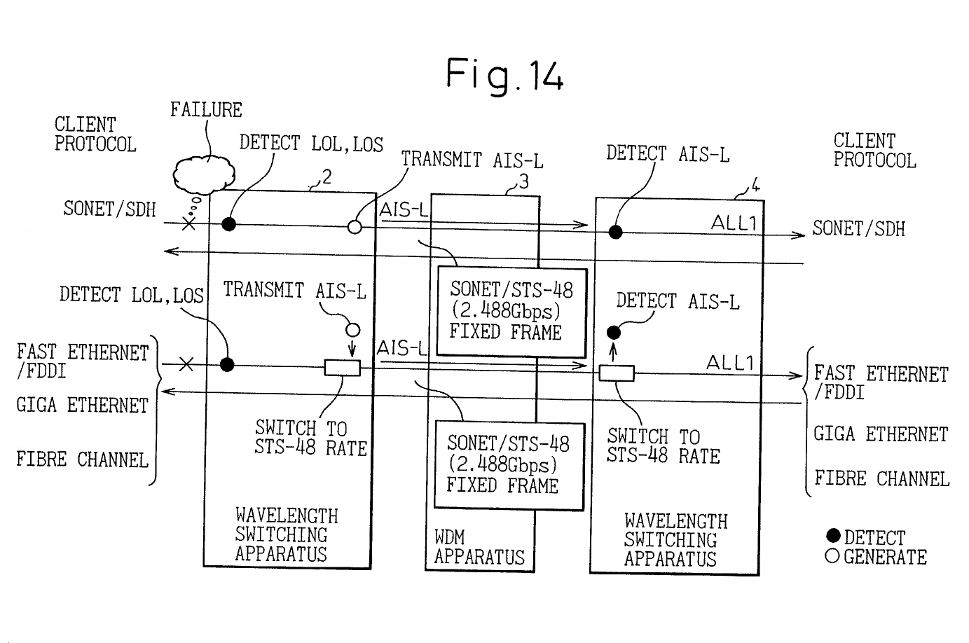

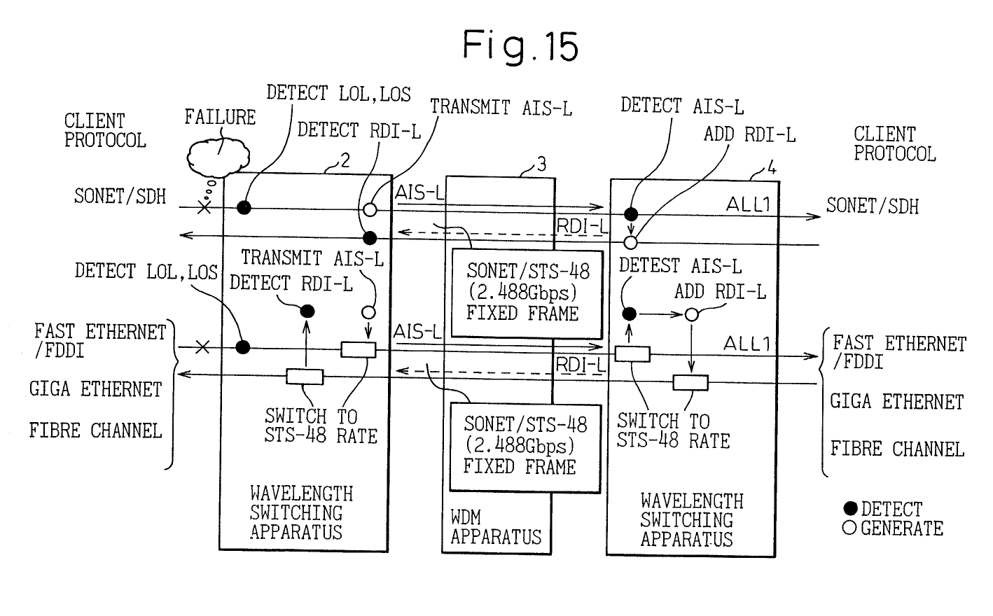

FIGS. 14 and 15 are diagrams illustrating the alarm transfer operation according to the first embodiment so far described.

As shown in FIG. 14, the alarm transfer operation after the clock has been switched due to the occurrence of a failure is exactly the same between the SONET/SDH protocol and other client protocols such as Fast Ethernet/FDDI, Gigabit Ethernet, and Fibre Channel. Therefore, according to the present invention, the alarm transfer operation can be carried out in a standardized manner without regard to the client protocol used.

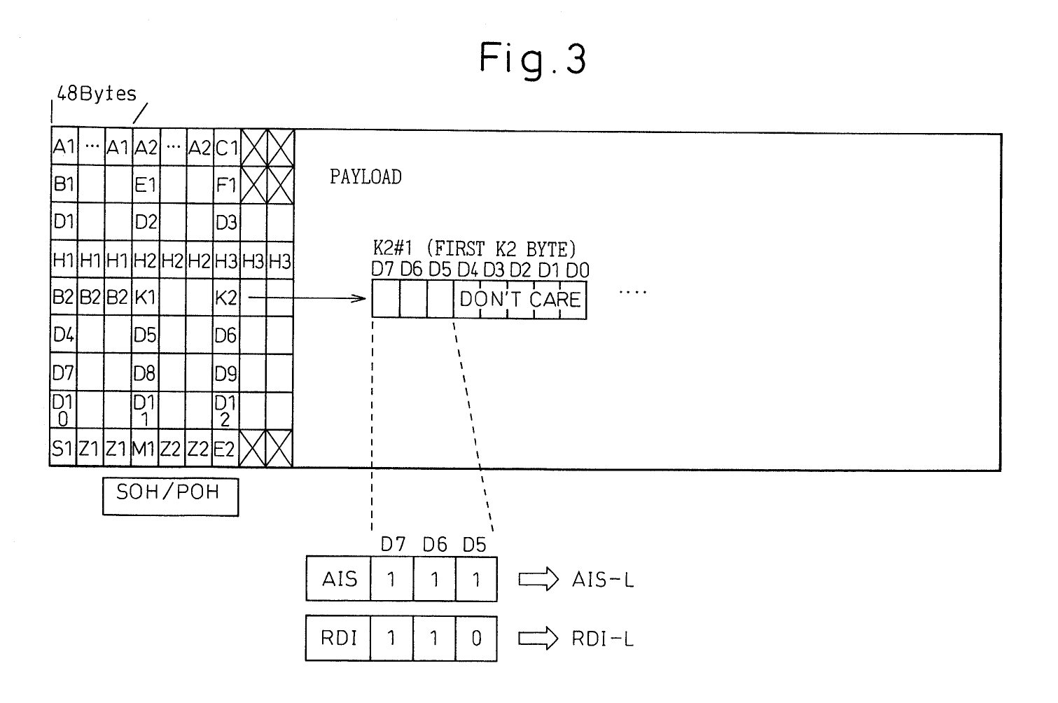

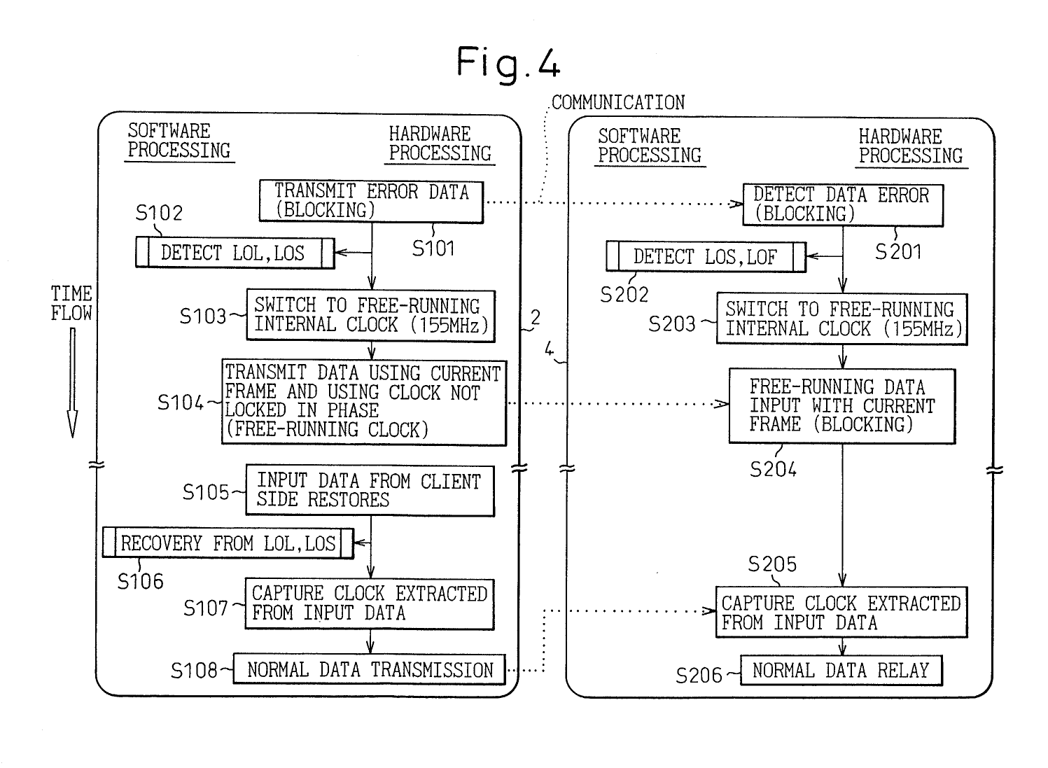

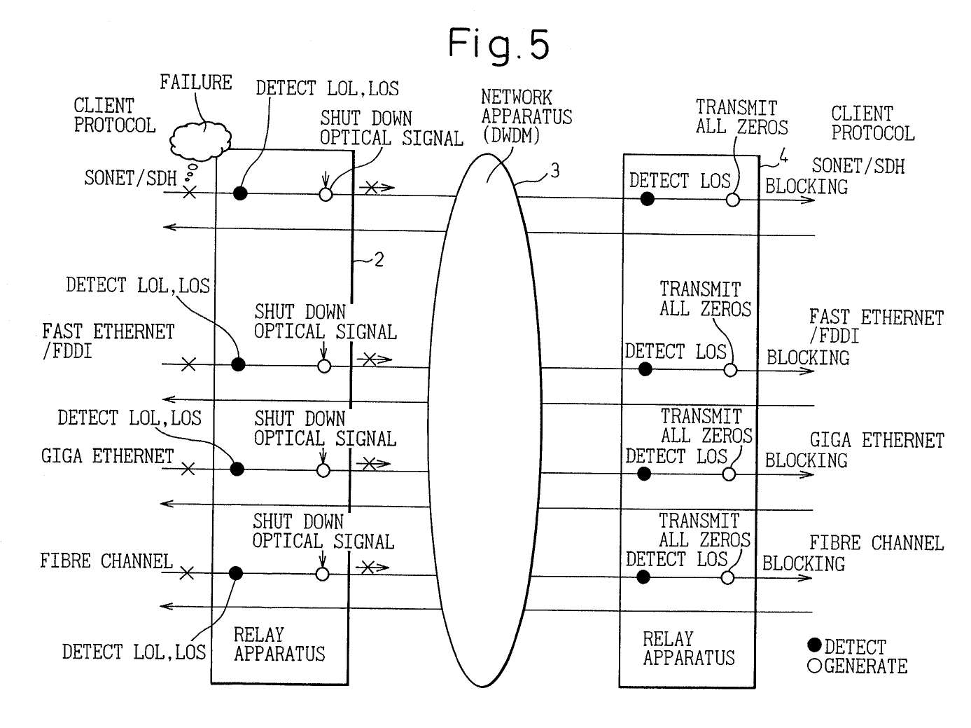

In FIG. 15, a responding operation, which is performed by the relay apparatus 4 that received the alarm, is added to the alarm operation of FIG. 14. The RDI-L previously described with reference to FIG. 3 is used for the response. The RDI-L itself is defined in the SONET/SDH protocol; therefore, in this example also, the alarm transfer operation and its associated responding operation can be performed in a standardized manner without regard to the client protocol used.

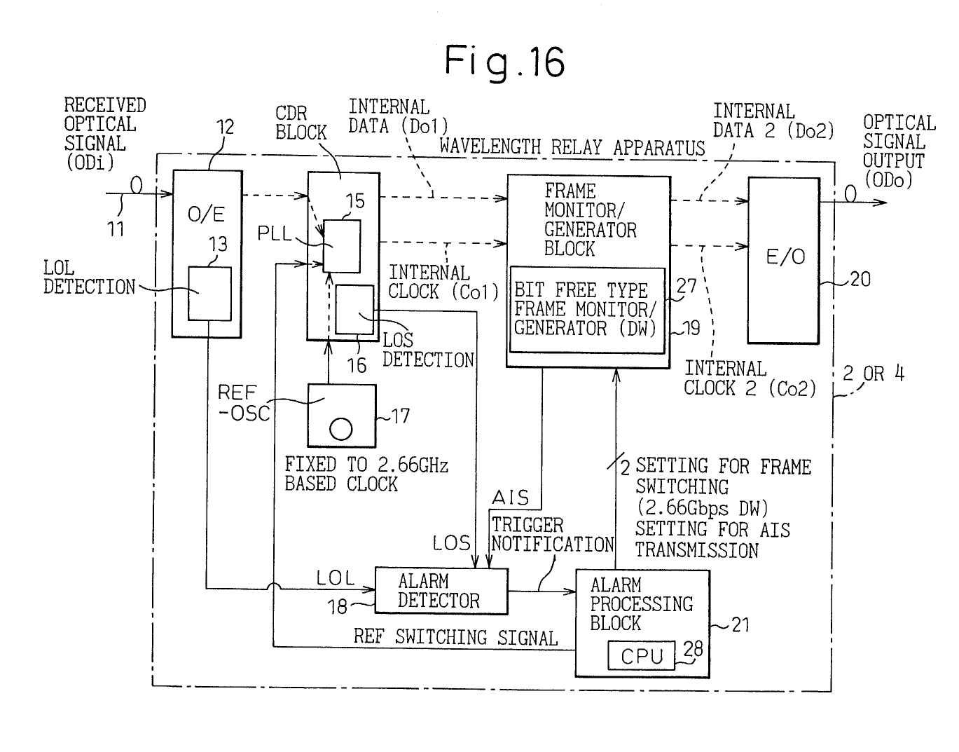

FIGS. 16 to 20 are diagrams showing another embodiment of the optical transmission apparatus implementing the operation of the present invention.

FIG. 16 shows the second embodiment of the optical transmission apparatus according to the present invention.

In this embodiment, instead of the SONET/SDH frame so far described, a digital wrapper (DW) frame defined in ITU-T G.709 recommendation is used for alarm processing. For this purpose, a bit-free type frame monitor/generator 27 for the DW is provided in the frame monitor generator block 19. The bit-free type frame monitor/generator 27 is constructed, for example, from a multi-function general-purpose communication controller or the like, and the setting of the frame format, communication processing by software, etc. are performed by the CPU 28 of the alarm processing block 21.

Generally, a digital wrapper requires a speed 7% higher than the data transmission speed because of the encapsulation of transmission data. Accordingly, for the reference oscillator 17, a 2.66-GHz (=2,488.32×1.07) oscillator is used by considering the STS-48 (2,488.32 MHz) that requires the highest data transmission speed. The configuration of the other constituent elements and their operations are the same as those in the first embodiment explained with reference to FIGS. 9 to 11.

FIGS. 17A to 17C are diagrams showing one example of the 2.66-Gbps DW frame structure.

FIG. 17A shows an example of the 2.66-Gbps DW frame in which the area consisting of columns 1 to 16 and rows 1 to 4 are used as the overhead area. In this example, the area of column 1 and row 1 is used for frame alignment, and an alarm frame corresponding to AIS-L in SONET/SDH is constructed by setting all the other bits to is, as shown in FIG. 17B.

Further, as shown in FIG. 17C, an example of the response frame corresponding to RDI-L in SONET/SDH is realized by inserting is in “BDI” headers within the overhead area. By making the same setting at both the transmitting and receiving ends, it becomes possible to transfer the AIS and BDI (RDI) using the 2.66-Gbps DW frame at the time of the occurrence of a failure. In this way, in an optical network where a plurality of client protocols are running in mixed fashion, an alarm can be transferred between relay apparatuses and detected at an endpoint apparatus by using the DW frame as the unified alarm transfer frame.

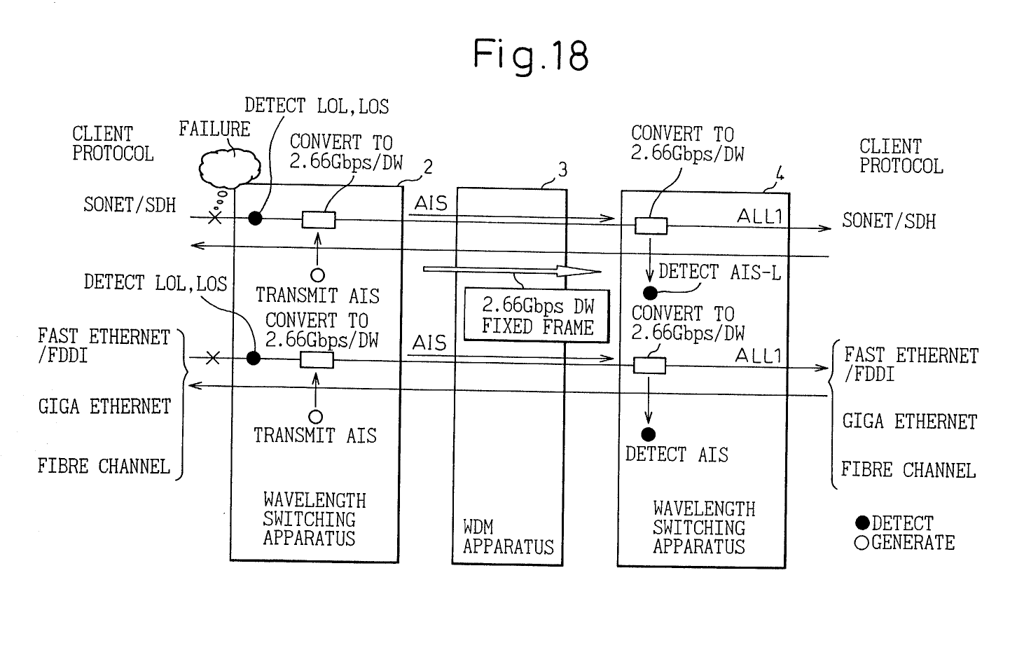

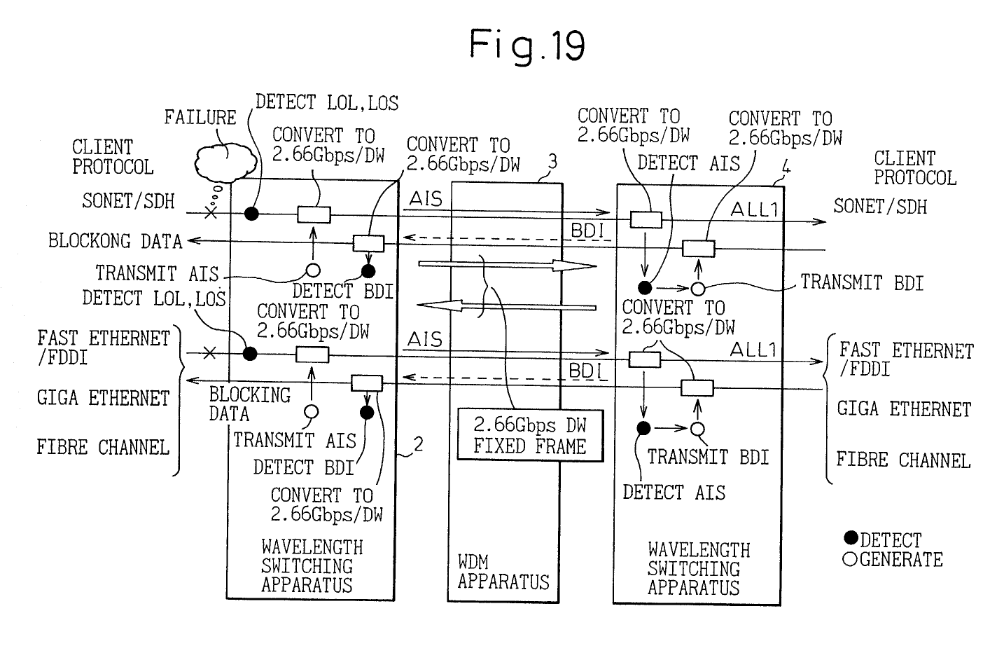

FIGS. 18 and 19 are diagrams illustrating the alarm transfer operation using the DW frame described above, and correspond to FIGS. 14 and 15, respectively, which show the alarm transfer operation using the SONET/SDH frame.

As shown in FIG. 18, in the alarm transfer operation after the clock has been switched due to the occurrence of a failure, DW frames of the same format are used regardless of whether the protocol used is the SONET/SDH protocol or a non-SONET/SDH protocol such as Fast Ethernet/FDDI, Gigabit Ethernet, or Fibre Channel. Accordingly, the alarm transfer operation can be carried out in a standardized manner without regard to the client protocol used.

In FIG. 19, a responding operation, which is performed by the relay apparatus 4 that received the alarm, is added to the alarm operation of FIG. 18. The BDI shown in FIG. 17C is used for the response. Therefore, in this example also, the alarm transfer operation and its associated responding operation can be performed in a standardized manner without regard to the client protocol used.

As described above, according to the present invention, in an optical network where SONET/SDH, a client protocol that can perform network management and client management using a dedicated frame, and other client protocols, such as Fast Ethernet/FDDI, Gigabit Ethernet, etc. that do not have such dedicated frames and, therefore, cannot be readily used for network management and maintenance, are running in mixed fashion, alarm information indicating a failure occurring between an endpoint and a relay apparatus can be transferred using a unified alarm frame, thus enabling alarm monitoring and control between relay apparatuses without burdening the network apparatuses forming the optical network.

1. A transmission apparatus which is connected to a network where transparent data transmissions are performed using a plurality of client protocols, and which is designed to accommodate at least one of the plurality of protocols as a primary client protocol, wherein
the transmission apparatus is equipped with an alarm transfer device for transferring alarm information indicating the occurrence of a failure to a destination transmission apparatus via the network, and
the alarm transfer device transfers the alarm information by using an alarm frame created based on a prescribed client protocol unified among the plurality of client protocols.

2. A transmission apparatus as claimed in claim 1,
wherein the alarm transfer device performs switching from the primary client protocol to the prescribed unified client protocol when a failure is detected, and performs switching from the prescribed unified client protocol to the primary client protocol when recovery from the failure is detected.

3. A transmission apparatus as claimed in claim 2, wherein, when a failure is detected, switching is made to a clock to be used by the prescribed unified client protocol and, when recovery from the failure is detected, switching is made to a clock to be used by the primary client protocol.

4. A transmission apparatus as claimed in claim 1, wherein the alarm transfer device performs switching from the primary client protocol to the prescribed unified client protocol when the alarm frame is received from the destination transmission apparatus and performs switching from the prescribed unified client protocol to the primary client protocol when the alarm frame is no longer received.

5. A transmission apparatus as claimed in claim 4, wherein, when the alarm frame is received, switching is made to a clock to be used by the prescribed unified client protocol, and when the alarm frame is no longer received, switching is made to a clock to be used by the primary client protocol.

6. A transmission apparatus as claimed in claim 1, wherein the prescribed unified client protocol is a protocol having a dedicated frame for network management and maintenance, and the primary client protocol is a protocol that does not have a dedicated frame for network management and maintenance.

7. A transmission apparatus as claimed in claim 1, wherein the alarm frame is a SONET/SDH frame.

8. A transmission apparatus as claimed in claim 1, wherein the alarm frame is a digital wrapper frame.
